(19) United States
(12) Patent Application Publication
(10) Pub. No.: US 2017/0317311 A1
(43) Pub. Date: Nov. 2, 2017

(54) OPTOELECTRONIC DEVICE WITH A FUSE

(71) Applicant: Osram OLED GmbH, Regensburg (DE)

(72) Inventors: Michael Popp, Freising (DE); Silke Scharner, Regensburg (DE)

(73) Assignee: Osram OLED GmbH, Regensburg (DE)

(21) Appl. No.: 15/527,719

(22) PCT Filed: Oct. 28, 2015
(86) PCT No.: PCT/EP2015/074951

§ 371 Date: May 18, 2017

(30) Foreign Application Priority Data
Nov. 18, 2014 (DE) 10 2014 223 495.6

(51) Int. Cl. H01L 51/52

(52) U.S. Cl. CPC H01L 51/5212; H01L 51/5234; H01L 51/5228; H01L 51/5215; H01L 2251/308; H01L 2251/5392

(57) ABSTRACT

An optoelectronic device with a first electrode is disclosed. The first electrode includes a plurality of electrode elements, which are arranged separately from one another, such that an intermediate space is located between them. The first electrode further includes a conductive structure, which is designed in such a way that it connects adjacent electrode elements to one another in an electrically conductive manner and in the process forms a fuse which acts between the connected adjacent electrode elements. The conductive structure includes a conductive structure layer, which adjoins the electrode elements and connects the adjacent electrode elements to one another in an electrically conductive manner and in the process acts as the fuse, and/or the conductive structure extends in the space between the electrode elements, and connects the adjacent electrode elements to one another in an electrically conductive manner via the intermediate space and thereby acts as the fuse.

### RELATED APPLICATIONS

The present application is a national stage entry according to 35 U.S.C. §371 of PCT application No.: PCT/EP2015/074951 filed on Oct. 28, 2015, which claims priority from German application No.: 10 2014 223 495.6 filed on Nov. 18, 2014, and is incorporated herein by reference in its entirety.

### TECHNICAL FIELD

The present disclosure relates to an optoelectronic device with a fuse and a method for producing such an optoelectronic device.

### BACKGROUND

US 2013187186 A1 discloses a light-emitting optoelectronic device, in which an electrode consists of a plurality of electrode elements arranged separately. These are supplied with electricity via separate supply conductors equipped with fuses, so that in the event of a short circuit they are individually disconnected from a power source, to prevent any further damage to the optoelectronic device.

### SUMMARY

The object of the present disclosure is to provide such an overcurrent protection with simpler means. This object is achieved by means of the features of the independent claims. Preferred designs are specified in claims dependent thereon.

In accordance with one embodiment an optoelectronic device includes an electrode, which hereafter is designated as a first electrode and advantageously has a layer-like design. Layers as well as layers having discontinuities are considered to be layer-like. The first electrode includes a plurality of electrode elements that are arranged separately from one another, such that an intermediate space lies between them, and a conductive structure.

The conductive structure connects the electrode elements together in an electrically conductive manner and in the process forms a fuse that acts between the connected adjacent electrode elements.

Either the conductive structure includes a conductive structure layer, which adjoins the electrode elements and connects adjacent electrode elements to one another in an electrically conductive manner and in the process acts as the fuse, or else it extends in the space between the electrode elements and connects adjacent electrode elements to one another in an electrically conductive manner via the intermediate space and in the process acts as the fuse, or else the conductive structure includes the conductive structure layer and also extends in the intermediate space between the electrode elements, wherein on the one hand the conductive structure layer adjoining the electrode elements connects adjacent electrode elements to one another in an electrically conductive manner and in the process acts as the fuse and at the same time, the conductive structure connects adjacent electrode elements to each other in an electrically conductive manner via the intermediate space, in the process acting as the fuse.

The conductive structure is designed in such a way that it acts as a melting fuse between the electrode elements. In other words, the conductive structure is designed in such a way that in the event of an overcurrent it can melt before the electrode elements melt, so that it can thereby break the electrical connection formed by the conductive structure between adjacent electrode elements.

According to at least one embodiment the optoelectronic device includes a functional layer structure, which is suitable for emitting electromagnetic radiation when the functional layer structure is energized, wherein the conductive structure is set up to energize the functional layer structure and the functional layer structure covers the conductive structure.

In particular, this means that the conductive structure is not laterally separated from the functional layer structure, thus for example, is arranged next to the functional layer structure. On the contrary, in this embodiment the conductive structure forms, for example in conjunction with the electrode elements, a flat first electrode which is covered by the functional layer structure. The functional layer structure can, in particular, completely cover the conductive structure on the side thereof facing away from a carrier, for example a glass substrate. The functional layer structure is thus arranged in particular in a vertical direction above the conductive structure and can directly adjoin this, at least at some points. In this way it is possible to design the electrode elements which, for example, form highly transparent conductive islands, so small, for example so thin, that the dark spots that are formed during insulation of the failure areas are either barely visible or not visible at all to the human eye.

The optoelectronic device additionally advantageously includes a second electrode and the functional layer structure. The first and the second electrode are arranged relative to the functional layer structure such that this can be energized by means of the electrodes. The functional layer structure is suitable, given an appropriate energizing of the functional layer structure by means of the first and the second electrode, for emitting electromagnetic radiation. The second electrode can also have a layer-like structure.

The functional layer structure advantageously includes at least one functional layer that either includes an organic material or consists of an organic material. Particularly advantageously, the optoelectronic device is an organic light-emitting diode (OLED), e.g. an OLED, which emits light through a cover glass and/or a substrate.

The optoelectronic device can be set up to emit the electromagnetic radiation, which can be emitted by means of the first and the second electrode when the functional layer structure is energized, through the first and/or the second electrode. The optoelectronic device is advantageously set up, however, to emit the electromagnetic radiation, which can be emitted by means of the first and the second electrode when the functional layer structure is energized, through the first electrode.

As previously described, the functional layer structure can be energized by means of the two electrodes. In particular, the functional layer structure is capable of being energized by means of the second electrode and the electrode elements of the first electrode. It may be the case, however, that areas located between the electrode elements emit no electromagnetic radiation.

In accordance with a preferred embodiment therefore, the conductive structure is designed and arranged in relation to the functional layer structure in such a way that the functional layer structure can be energized by means of the conductive structure, or the conductive structure and the electrode elements are designed and arranged in relation to the functional layer structure in such a way that the functional layer structure can be energized both by means of the conductive structure and also by means of the electrode elements. Accordingly, in these preferred embodiments areas of the functional layer structure located between the electrode elements can also be energized by means of the first electrode, so that they emit electromagnetic radiation.

According to a particular preferred embodiment, the first electrode and the second electrode are designed and arranged relative to the functional layer structure in such a way that the functional layer structure can be energized by means of the first and the second electrode in such a way that a current density at a position of the functional layer structure located within one of the electrode elements, as seen in projection onto a layer surface of the first electrode, differs from a current density at a position of the functional layer structure located centrally in the intermediate space between two boundary surfaces of the electrode elements, as seen in projection onto the surface layer of the first electrode, by less than 50%, advantageously less than 20% and particularly advantageously by less than 5%. Either one of the two layer-parallel boundary surfaces of the layer-like electrode can be designated as the layer surface.

Both in a region within one of the electrodes elements and in a region of the conductive structure between the electrode elements, the first electrode advantageously has a transparency of at least 50%, advantageously at least 75%, at a wavelength of 500 nm.

Advantageously, a surface resistivity (i.e. a resistance normalized to a unit area) of the first electrode in a region of the conductive structure between the electrode elements is greater than in an area of one of the electrode elements. It is thus possible to ensure that in the event of an overcurrent, the region of the conductive structure located between the electrode elements is heated more quickly than the region of the electrode element, to ensure that melting occurs and thus its action as a fuse. The above mentioned surface resistances can in the case of a layer-like first electrode in particular be expressed in terms of the above mentioned layer surface of the first electrode.

In accordance with a preferred embodiment the surface resistivity of the first electrode in the region of the conductive structure is greater than in the region of the electrode elements by at least a factor of 1.5, particularly advantageously by at least a factor of 2 and quite particularly advantageously by at least a factor of 5.

For the action as a fuse it is also advantageous if the conductive structure has a lower melting point than the electrode elements. Accordingly, a melting point of the first electrode is advantageously lower in the region of the conductive structure than in the region of the electrode elements, particularly advantageously at least 3° C. lower or at least 10° C. lower or even at least 20° C. lower.

For the action as a fuse it is further advantageous if the conductive structure can absorb less heat per unit area than the electrode elements. Accordingly, the specific heat capacity per unit area of the first electrode is advantageously lower in the region of the conductive structure than in the region of one of the electrode elements, particularly advantageously at least 10% lower or at least 30% lower or even at least 50% lower.

In accordance with a preferred embodiment the conductive structure includes nano-conductive elements with a diameter of less than 100 nm, advantageously less than 50 nm, which act as the fuse. The nano-conductive elements can also have a diameter that is greater than 5 μm and less than 100 μm, or a diameter that is greater than 5 μm and less than 50 μm. The conductive structure can also consist of the previously described nano-conductive elements.

The nano-conductive elements are advantageously elongated nano-conductive elements which, for example, can have a length of at least five times, advantageously ten times their diameter.

The nano-conductive elements can in particular include or consist of silver and/or gold and/or copper and/or indium tin oxide and/or carbon.

In particular, the previously mentioned nano-conductive elements can be carbon nanotubes and/or nanowires made of gold or silver or copper.

In particular, the conductive structure may include or consist of carbon nanotubes and/or nanowire lattices and/or nanowire networks, as described in A. Kumar, C. Zhou: The Race To Replace

Tin-Doped Indium Oxide: Which Material Will Win?, ACS Nano 2010, Vol. 4, No. 1, pages 11-14. Suitable nanowires, nanotubes and nanorods for the conductive structure are also discussed in C. Li, X. Yu : Silver nanowire-based transparent flexible, and conductive thin film., Nanoscale Research Letters 2011, 6:75. In addition, suitable nanowires and nanotubes for the conductive structure are described in D. Hecht, L. Hu, G. Irvin: Emerging Transparent Electrodes Based on Thin Films of Carbon Nanotubes, Graphene, and Metallic Nanostructures., Advanced Materials 2011, 23, pp. 1482-1513.

The nano-conductive elements described here can be incorporated, for example, into a matrix material. The matrix material can be designed, for example, to be radiation-permeable, or transparent. Further, it is possible for the matrix material to be electrically insulating. The density of the nano-conductive elements in the matrix material can be set in such a way that in the event of a short circuit the nano-conductive elements that are the supply lead to the electrodes elements which, for example, form highly transparent conductive islands, break open and thus insulate the region. The electrodes elements can be so small that the dark spots that are formed during insulation of the failure area are not visible to the human eye. In addition, the use of a transparent matrix material has the advantage that no non-illuminating areas are formed.

In accordance with a preferred embodiment the electrode elements either include or consist of a conductive layer. For example, each of the electrode elements may include or consist of a conductive layer. The conductive layer advantageously includes or consists of indium tin oxide.

Alternatively the electrode elements can also include or consist of the previously described nano-conductive elements with a diameter of less than 100 nm or less than 50 nm or between 5 nm and 100 nm or between 5 nm and 50 nm. These nano-conductive elements of the electrode elements are not designed as a fuse however, for example because a surface resistivity of the first electrode in a region of the conductive structure between the electrode elements is greater than in a region within one of the electrode elements and/or a melting point of the first electrode in the region of the conductive structure is lower than in the region of one of the electrode elements and/or a specific heat capacity per unit area of the first electrode in the region of the conductive structure is less than in the region of one of the electrode elements.

A lower surface resistivity in the region of the electrode elements can be achieved, for example, by using a nanoelement solution for the electrode elements, which contains nanoelements that on average are shorter than the nanoelements of the nanoelement solution from which the conductive structure is created, so that the electrode elements created have a higher nanoelement density, for example in the matrix material, than the conductive structure.

The electrode elements advantageously have an extension of less than 200 μm, advantageously less than 100 μm and advantageously less than 50 μm in each direction.

In accordance with a preferred embodiment, the electrode elements, viewed in projection onto the layer surface of the first electrode in each direction, have an extension of less than 200 μm, advantageously less than 100 μm and particularly advantageously less than 50 μm.

Due to the previously mentioned small dimensions of the electrode elements, it is possible that a melting of the electrical connection produced via the conductive structure of one or a small number of the electrode elements is either difficult or impossible to identify from the luminous image of the optoelectronic device.

A distance between the electrode elements is advantageously less than 20 μm or less than 10 μm, and particularly advantageously less than 5 μm. This means that a voltage drop across the main surface of the first electrode can be reduced if the resistance of the first electrode in an area of the conductive structure between the electrode elements is greater than in an area of one of the electrode elements.

In accordance with a preferred embodiment, the second electrode includes a plurality of second electrode elements, which are arranged separated from one another so that a second intermediate space lies between them, and a second conductive structure, which is designed such that it connects adjacent second electrode elements to one another in an electrically conductive manner and in the process forms a second fuse which acts between the connected adjacent second electrode elements. The second conductive structure includes a second conductive structure layer, which adjoins the second electrode elements and connects adjacent second electrode elements to one another in an electrically conductive manner and in the process acts as the second fuse, and/or it extends in the second intermediate space between the second electrode elements and connects the adjacent second electrode elements to one another in an electrically conductive manner via the second intermediate space and thereby acts as the second fuse.

The second electrode can therefore be structured identically to the first electrode. Furthermore, it may include one or a plurality of the above described preferred features of the first electrode, without being structured identically to the first electrode.

In accordance with one embodiment, a method for producing the previously described optoelectronic device with melting fuse includes the step of the creation of the layer-like first electrode. This step in turn includes the sub-step of creating the plurality of electrode elements which are arranged separately from one another, so that an intermediate space lies between them, and the partial step of creating the conductive structure which is designed in such a way that it connects adjacent electrode elements to one another in an electrically conducting manner and in the process forms a fuse, which acts between the connected adjacent electrode elements. As described above, the second conductive structure created includes a conductive structure layer, which adjoins the electrode elements and connects adjacent electrode elements to one another in an electrically conductive manner and in the process acts as the second fuse, and/or the conductive structure extends in the intermediate space between the electrode elements and connects adjacent electrode elements to one another in an electrically conductive manner via the intermediate space and thereby acts as the fuse.

In accordance with one embodiment the method also includes the steps of creating a functional layer structure and the creation of a second electrode, wherein the first and the second electrode and the functional layer structure are created in such a way that the functional layer structure is suitable for emitting electromagnetic radiation when the functional layer structure is energized by means of the first electrode and by means of the second electrode.

In accordance with one embodiment, the step of creating the second electrode includes the sub-steps of creating the plurality of second electrode elements, which are arranged separated from one another, so that a second intermediate space lies between them, and of creating the second conductive structure, which connects the adjacent second electrode elements to one another in an electrically conductive manner and in the process forms a second fuse which acts between the connected adjacent second electrode elements. As described, the second conductive structure includes the second conductive structure layer and/or extends in the second intermediate space between the second electrode elements and connects the adjacent second electrode elements to one another in an electrically conductive manner via the second intermediate space and thereby acts as the second fuse.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows an optoelectronic device according to a first embodiment,

FIG. 2 shows an optoelectronic device according to a second embodiment,

FIG. 3 shows an optoelectronic device according to a third embodiment,

FIG. 4 shows an optoelectronic device according to a fourth embodiment,

FIG. 5 shows an optoelectronic device according to a fifth embodiment,

FIG. 6 shows an optoelectronic device according to a sixth embodiment,

FIG. 7 shows a method for producing an optoelectronic device in accordance with one of the first five embodiments,

FIG. 8 shows a method for producing an optoelectronic device in accordance with the sixth embodiment.

### DETAILED DESCRIPTION

The optoelectronic devices 1 shown in FIGS. 1, 2 and 3 according to the first three embodiments all include a layer-like first electrode 20, a layer-like second electrode 30 and a functional layer structure 10, which is suitable for emitting electromagnetic radiation when the functional layer structure 10 is energized by means of the first and second electrodes 20, 30 with a suitable current amplitude or voltage.

The first electrode 20 in these embodiments includes a plurality of electrode elements 21 that are arranged separately from one another so that an intermediate space lies between them, and a conductive structure 22, which connects adjacent electrode elements 21 to one another in an electrically conductive manner and in this connection acts as a fuse.

In the first embodiment in accordance with FIG. 1 the conductive structure 22 extends only in the intermediate space between the electrode elements 21 and connects adjacent electrode elements to one another in an electrically conductive manner via the intermediate space and in this connection acts as a fuse.

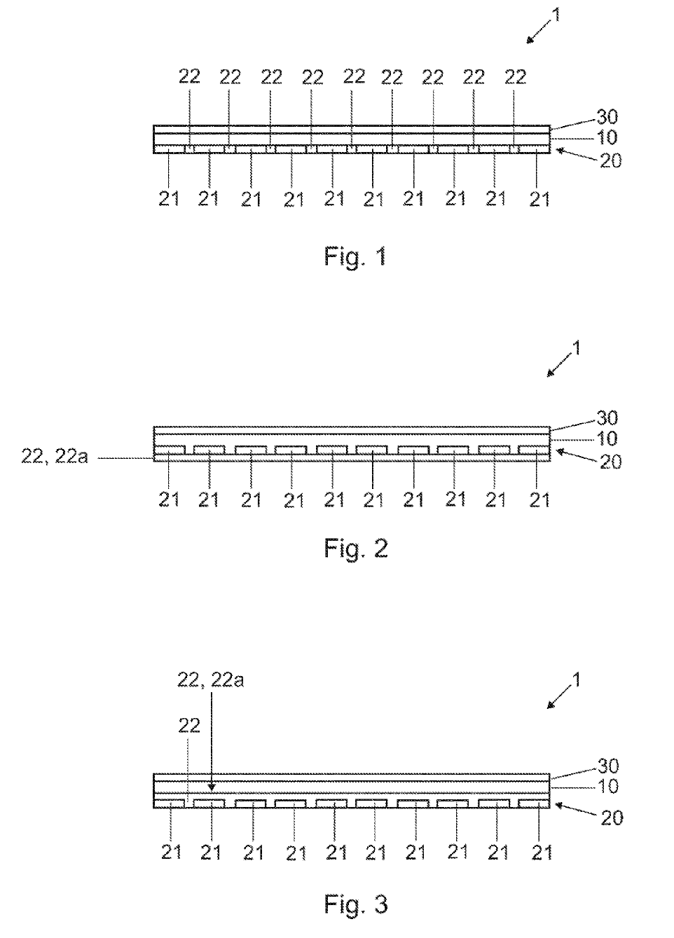

In the case of the second embodiment in accordance with FIG. 2, the conductive structure 22 consists of a conductive structure layer 22a, which adjoins the electrode elements 21 and connects adjacent electrode elements 21 to one another in an electrically conductive manner and thereby acts as a fuse.

In the third embodiment in accordance with FIG. 3, the conductive structure 22 extends in the intermediate space between the electrode elements 21 and connects adjacent electrode elements 21 to one another in an electrically conductive manner via the intermediate space and also includes a conductive structure layer 22a, which adjoins the electrode elements 21 and connects adjacent electrode elements 21 to one another in an electrically conductive manner. Both previously described connections are designed as fuses acting between the electrode elements 21, so that in the event of an overcurrent condition these two connections are broken by melting the conductive structure 22.

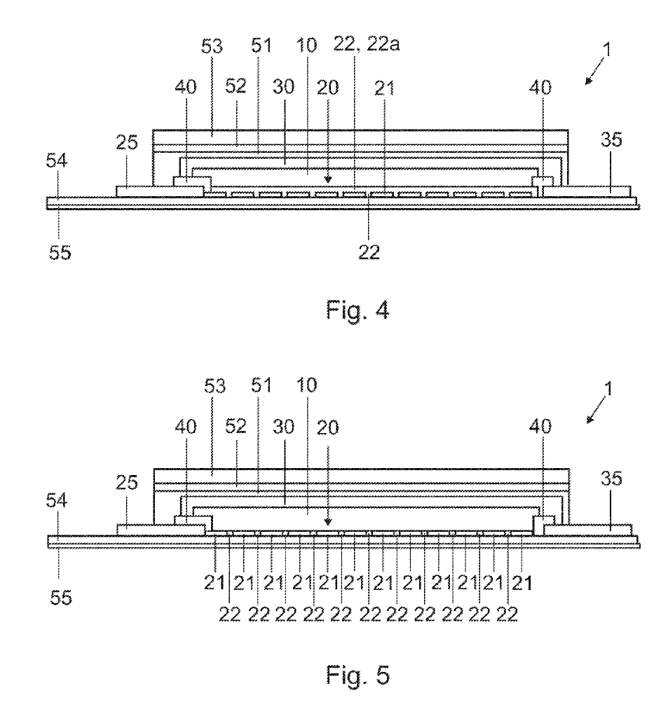

The optoelectronic device 1 shown in FIG. 4 according to a fourth embodiment also includes a first electrode 20, a second electrode 30 and a functional layer structure 10. The functional layer structure 10 is suitable for emitting electromagnetic radiation through the first electrode 20 when the functional layer structure 10 is energized by means of the electrodes 20, 30 with a suitable current amplitude or voltage.

The first electrode 20 in turn includes a plurality of electrode elements 21 and a conductive structure 22, which extends in the intermediate space between the electrode elements 21 and connects adjacent electrode elements 21 to one another in an electrically conductive manner via the intermediate space and also includes a conductive structure layer 22a, which adjoins the electrode elements 21 and connects adjacent electrode elements 21 to one another in an electrically conductive manner.

The optoelectronic device 1 of FIG. 4 is an organic light emitting diode (OLED). During the operation of the OLED the light generated by the functional layer structure 10 is emitted through the first electrode 20 and the glass substrate 54. On the opposite side of the glass substrate 54 from the electrode 20 an extraction film 55 is in turn arranged, which enhances the light extraction.

Both in a region inside one of the electrode elements 21 and in a region between the electrode elements 21, the first electrode 20 has a transparency to light of least 75% at a wavelength of 500 nm. This is achieved in the present embodiment by the fact that the conductive structure consists of nano-conductive elements, such as carbon nanotubes and/or nanowires made of gold or silver, which predominantly have a diameter of less than 100 nm, wherein the conductive structure has a sufficiently small layer thickness to allow the necessary light transmission. The electrode elements 21 in turn consist of indium tin oxide (abbreviation: ITO) and are sufficiently thin to provide the necessary light transmission.

Alternatively, both the conductive structure 22 and the electrode elements 21 could consist of such nano-conductive elements, wherein only the nano-conductive elements of the conductive structure 22 located between the electrodes are designed as fuses.

So that the conductive structure 22 and not the electrode elements 21 act as fuses, the surface resistivity of the first electrode in an area of the conductive structure 22 between the electrode elements 21 is greater than in an area of one of the electrode elements 21. In addition, a melting point of the conductive structure 22 could also be lower than that of one of the electrode elements 21 and/or a specific heat capacity per unit area of the first electrode 20 in the area of the conductive structure 22 could be lower than in the area of one of the electrode elements 21. In order to minimize the voltage drop across the electrode surface caused by the increased surface resistivity, the electrode elements 21 are spaced less than 5 μm apart from one another.

The second electrode 30, on the other hand, includes a flat electrode layer whose structure remains substantially constant over the entire area.

The OLED moreover has insulator structures 40, which prevent a short circuit between the two electrodes 20, 30, and terminals 25, 35 for connecting the electrodes 20, 30 to a power source. The electrodes 20, 30 and the functional layer structure are encapsulated by a thin-film coating 51 and thus protected against environmental influences. A further glass plate 53 is applied in turn onto the thin-film coating 51 by means of an adhesive 52, to additionally protect the OLED against damage.

The conductive structure 22 in the embodiment of FIG. 4 is in direct contact with the functional layer structure 10 over the entire surface, so that this can be energized evenly, resulting in a relatively homogenous luminous image being achieved. In this case, the functional layer structure 10 can therefore be energized by means of the two electrodes in such a way that a current density at a position of the functional layer structure 10 located within one of the electrode elements 21, as seen in projection onto a layer surface of the first electrode 20, differs from a current density at a position of the functional layer structure 10 located centrally in the intermediate space between two boundary surfaces of the electrode elements 21, as seen in projection onto the surface layer of the first electrode 20, by less than 5%.

If in the OLED in accordance with the fourth embodiment a local short-circuit occurs between the two electrodes, 20, 30, e.g. due to particles introduced during the production, then during operation of the OLED the relevant electrode elements 21 of the first electrode 20 are disconnected from the power supply by the conductive structure 22 acting as a fuse. This means that damage to areas of the OLED that are not affected by the short-circuit can be avoided.

In order that the electrode elements 21 disconnected from the power supply do not unduly impair the luminous image of the OLED, the electrode elements 21 have an extension of less than 50 μm in each direction.

The fifth embodiment, shown in FIG. 5, is identical to the fourth embodiment, except for the difference that the conductive structure 22 only extends in the intermediate space between the electrode elements 21 and connects adjacent electrode elements 21 to one another in an electrically conductive manner via the intermediate space, but does not include the previously described conductive structure layer 22a, which adjoins the electrode elements 21 and connects adjacent electrode elements 21 to one another in an electrically conductive manner.

Both the electrode elements 21 and the conductive structure 22 are in direct contact with the functional layer structure 10, so that in operation these are energized with both the electrode elements 21 and the conductive structure 22, enabling a relatively homogenous luminous image to be achieved. In the present case, the functional layer structure 10 can be energized by means of the two electrodes in such a way that a current density at a position of the functional layer structure located within one of the electrode elements, as seen in projection onto a layer surface of the first electrode, differs from a current density at a position of the functional layer structure located centrally in the intermediate space between two boundary surfaces of the electrode elements, as seen in projection onto the surface layer of the first electrode, by less than 20%.

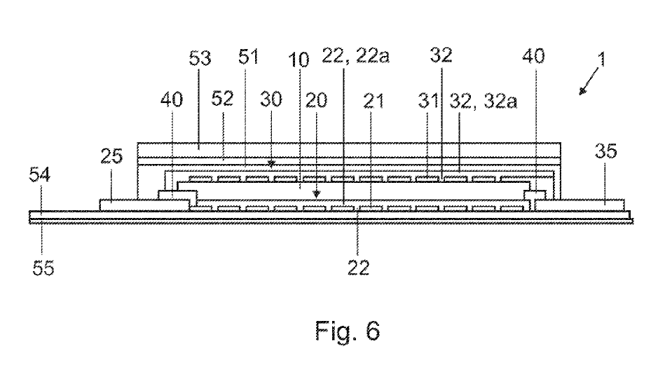

The optoelectronic device 1 shown in FIG. 6 in accordance with the sixth embodiment is structured identically to that of the fourth embodiment, with the single difference that in this optoelectronic device 1 of FIG. 6 the second electrode 30 is structured identically to the first electrode 20, i.e. also include a conductive structure 32 and electrode elements 31. Consequently, in the present embodiment both the conductive structure 22 of the first electrode 20 and the conductive structure 32 of the second electrode 30 act as fuses.

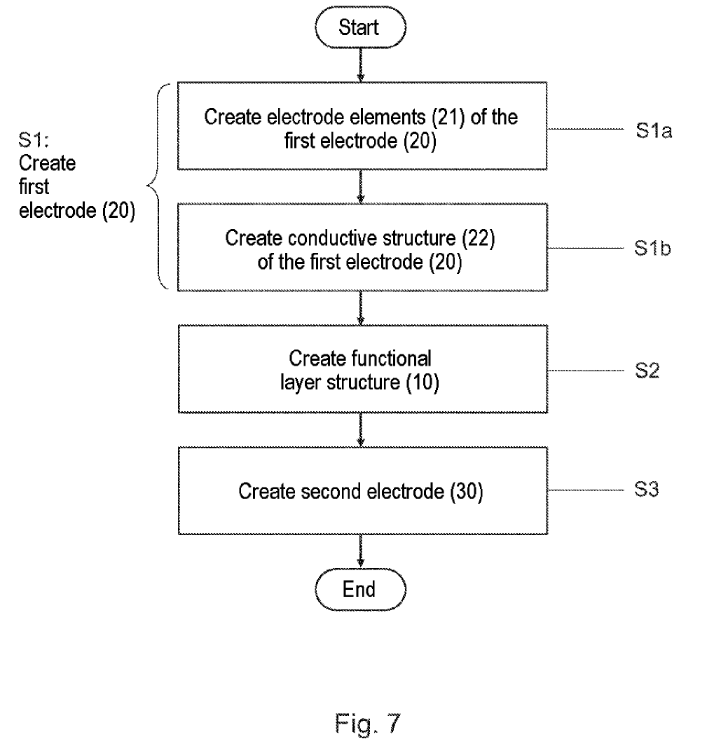

The method shown in FIG. 7 for producing the previously described optoelectronic device in accordance with any of the embodiments to 5 includes the steps of the creation S1 of the first electrode 20, the creation S2 of the functional layer structure 10 and the creation S3 of the second electrode 30. The step of creating S1 the first electrode 20 in turn includes the sub-step Sla of the creation of plurality of electrode elements 21 and the sub-step S1b of the creation of the conductive structure 22.

For example, for creating S1a the electrode elements 21 of the first electrode 20 of the optoelectronic device 1 in accordance with any of the embodiments 3 or 4, a structured indium tin oxide layer is first evaporated by means of chemical vapor deposition (abbreviated to “CVD”) onto a substrate, e.g. the glass substrate 54, using a suitable shadow mask. A solution containing nanowires is then applied to the resulting electrode elements 21, so that after evaporation of the solution between the electrode elements 21 and on the electrode elements 21, a conductive structure 22 consisting of nano-conductive elements remains (Step S1b). After this creation of the first electrode 20, the functional layer structure 10 and the second electrode 30 are evaporated by means of CVD (steps S2 and S3), as is also the case with conventional OLEDs.

Alternatively, initially a full-surface electrode followed by a full-surface functional layer structure could also be evaporated onto a substrate, wherein a structured indium tin oxide layer (electrode elements) is then created on the latter by means of CVD and using a suitable shadow mask. A solution containing nanowires is then applied to the latter in turn, so that after evaporation of the solution between the electrode elements and on the electrode elements, a conductive structure consisting of nano-conductive elements remains.

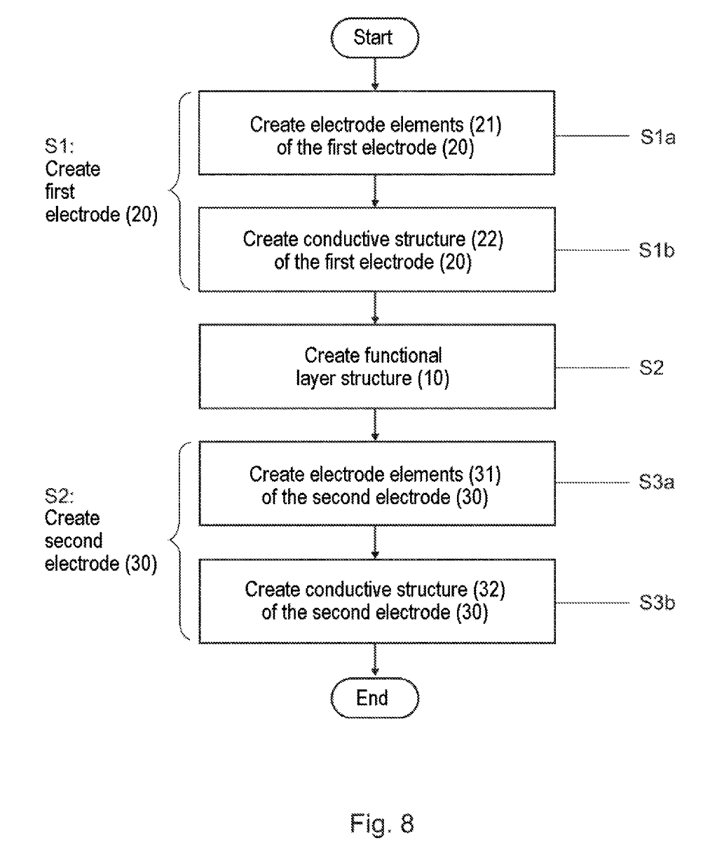

The method shown in FIG. 8 for producing the previously described optoelectronic device 1 in accordance with the sixth embodiment also includes the steps of the creation S1 of the first electrode 20, the creation S2 of the functional layer structure 10 and the creation S3 of the second electrode 30. The step of creating S1 the first electrode 20 in turn includes the sub-step S1a of the creation of plurality of electrode elements 21 and the sub-step S1b of the creation of the conductive structure 22. Analogously to this, the step of the creation S3 of the second electrode 30 includes the sub-step S3a of the creation of the plurality of electrode elements 31 and the sub-step S3b of the creation of the conductive structure 32.

For example, the electrode elements 21 of the first electrode 20 can be created by means of CVD and using a suitable shadow mask of indium tin oxide (ITO) (step S1a). A solution containing nanowires is then applied to these electrode elements 21, so that after evaporation of the solution between the electrode elements 21 and on the electrode elements 21 a conductive structure 22 consisting of nanowires remains (step S1b). After this creation of the first electrode the functional layer structure 10 is then evaporated on (step S2). On this, analogously to the electrode elements 21, the electrode elements 31 are then created (step S3a) by means of CVD and using a suitable shadow mask of indium tin oxide (ITO), and on these electrode elements 31 a solution containing nanowires is then applied, so that after evaporation of the solution between the electrode elements 31 and on the electrode elements 31 a further conductive structure 32 consisting of nanowires remains (step S3b).

As described above, both the electrode elements 21 and/or 31 as well as the conductive structure(s) 22 and/or 32 may also consist of nanoelements, in particular nanowires. The electrode elements 21 and/or 31 are in this case created e.g. by a full-surface application of a nanoelement layer—which can be effected e.g. by drying a full-surface nano element solution—followed by local removal of the applied nanoelement layer by laser ablation. The conductive structure 22 and/or 32 is then created as described previously by applying and drying a further nanoelement solution. A lower surface resistivity in the region of the electrode elements 21 and/or 31 can be achieved, for example, by using a nanoelement solution for the electrode elements, which contains nanoelements that on average are shorter than the nanoelements of the nanoelement solution from which the conductive structure is created, so that the electrode elements created have a higher nanoelement density than the conductive structure.

To create the optoelectronic devices described in the examples of FIGS. 1 and 5, in which the conductive structure only extends between the electrodes, it is possible, for example, to apply the nanowire solution to the electrode elements with a blade in such a way that the conductive structure 22 and/or 32 formed of nanoelements after drying the nanowire solution only extends between the electrode elements 21 and/or 31.

Also, in the production method previously described in connection with FIGS. 7 and 8, both the electrode elements 21 and/or 31 as well as the conductive structure 22 and/or 32 can be implemented as a coating. For example, a thinner ITO layer can be applied over the full surface, which forms the conductive structure layer of the conductive structure, followed by the electrode elements which are created as an ITO layer structured by means of a shadow mask. In particular the first electrode 20 in accordance with the second embodiment can thereby be created, in which the conductive structure only consists of the conductive structure layer 21a, but does not extend in the intermediate spaces between the electrode elements 21.

The optoelectronic device has been described by reference to a number of embodiments in order to illustrate the underlying idea. The embodiments are not limited to specific combinations of features. Even if some of the features and designs have only been described in conjunction with a particular embodiment or individual embodiments, they can in each case be combined with other features from other embodiments. It is also possible to omit or add individual features or particular designs shown in embodiments, provided the general technical teaching remains realized.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic device comprising a first electrode,
wherein the first electrode comprises a plurality of electrode elements, which are arranged separately from one another, such that an intermediate space is located between them,
wherein the first electrode further comprises a conductive structure, which is designed in such a way that it connects adjacent electrode elements to one another in an electrically conductive manner and in the process forms a fuse which acts between the connected adjacent electrode elements,
wherein the conductive structure comprises a conductive structure layer, which adjoins the electrode elements and connects the adjacent electrode elements to one another in an electrically conductive manner and in the process acts as the fuse, and/or the conductive structure extends in the space between the electrode elements, and connects the adjacent electrode elements to one another in an electrically conductive manner via the intermediate space and thereby acts as the fuse.

2. The optoelectronic device as claimed in claim 1, further comprising a functional layer structure, which is suitable for emitting electromagnetic radiation when the functional layer structure is energized, wherein the conductive structure is set up to energize the functional layer structure and the functional layer structure covers the conductive structure completely on the side of the conductive structure facing away from a substrate.

3. The optoelectronic device as claimed in claim 1, further comprising:
a second electrode and
a functional layer structure, wherein the functional layer structure is suitable for emitting electromagnetic radiation when the functional layer structure is energized by means of the first and the second electrode.

4. The optoelectronic device as claimed in claim 3, wherein the second electrode comprises a plurality of second electrode elements, which are arranged separately from one another, such that a second intermediate space lies between them,
wherein the second electrode further comprises a second conductive structure, which is designed in such a way that it connects adjacent second electrode elements to one another in an electrically conductive manner and in the process forms a second fuse which acts between the connected adjacent second electrode elements,
wherein the conductive structure comprises a second conductive structure layer, which adjoins the second electrode elements and connects the adjacent second electrode elements to one another in an electrically conductive manner and in the process acts as the second fuse, and/or the second conductive structure extends in the second intermediate space between the second electrode elements, and connects the adjacent second electrode elements to one another in an electrically conductive manner via the second intermediate space and thereby acts as the second fuse.

5. The optoelectronic device as claimed in claim 3, wherein the first electrode is designed in a layer-like manner and the first electrode and the second electrode are designed and arranged relative to the functional layer structure in such a way that the functional layer structure can be energized by means of the first and the second electrode in such a way that a current density at a position of the functional layer structure located within one of the electrode elements, as seen in projection onto a layer surface of the first electrode, differs from a current density at a position of the functional layer structure located centrally in the intermediate space between two boundary surfaces of the electrode elements, as seen in projection onto the surface layer of the first electrode, by less than 50%.

6. The optoelectronic device as claimed in claim 2, wherein the conductive structure is designed and arranged in relation to the functional layer structure in such a way that the functional layer structure can be energized by means of the conductive structure.

7. The optoelectronic device as claimed in claim 1, wherein both in a region inside one of the electrode elements and in a region of the conductive structure between the electrode elements, the first electrode has a transparency to light of least 50%, at a wavelength of 500 nm.

8. The optoelectronic device as claimed in claim 1,
wherein a surface resistivity of the first electrode in a region of the conductive structure between the electrode elements is greater than in a region within one of the electrode elements and/or
a melting point of the first electrode in the region of the conductive structure is lower than in the region of the electrode elements and/or
a specific heat capacity per unit area of the first electrode in the region of the conductive structure is less than in the region within one of the electrode elements.

9. The optoelectronic device as claimed in claim 1, wherein the conductive structure comprises nano-conductive elements with a diameter of less than 100 nm, preferably less than 50 nm, which act as the fuse.

10. The optoelectronic device as claimed in any of the previous claims claim 1, wherein the electrode elements comprise a conductive layer, which preferably comprises indium tin oxide.

11. The optoelectronic device as claimed in claim 1, wherein the electrode elements have an extension of less than 200 μm in each direction.

12. A method for producing an optoelectronic device, comprising the step of creating a first electrode, wherein the step of creating the first electrode further comprises:
creating a plurality of electrode elements, which are arranged separately from one another, so that an intermediate space lies between them, and
creating a conductive structure, which is designed in such a way that it connects adjacent electrode elements to one another in an electrically conductive manner and in the process forms a fuse which acts between the connected adjacent electrode elements,
wherein the conductive structure is created in such a way that it comprises a conductive structure layer, which adjoins the electrode elements and connects the adjacent electrode elements to one another in an electrically conductive manner and/or in the process acts as the fuse, and/or is created in such a way that it extends in the intermediate space between the electrode elements and connects the adjacent electrode elements to one another in an electrically conductive manner via the intermediate space and thereby acts as the fuse.

13. The method as claimed in claim 12, further comprising:
creating a functional layer structure and
creating a second electrode, wherein the first and the second electrode and the functional layer structure are created in such a way that the functional layer structure is suitable for emitting electromagnetic radiation when the functional layer structure is energized by means of the first electrode and by means of the second electrode.

14. The method as claimed in claim 13, wherein the step of creating the second electrode further comprises:
creating a plurality of second electrode elements, which are arranged separately from one another, so that an intermediate space lies between them, and
creating a second conductive structure, which is designed in such a way that it connects adjacent electrode elements to one another in an electrically conductive manner and in the process forms a second fuse which acts between the connected adjacent second electrode elements,
wherein the conductive structure is created in such a way that it comprises a conductive structure layer, which adjoins the second electrode elements and connects the adjacent second electrode elements to one another in an electrically conductive manner and in the process acts as the second fuse, and/or is created in such a way that it extends in the intermediate space between the second electrode elements and connects the adjacent second electrode elements to one another in an electrically conductive manner via the second intermediate space and thereby acts as the second fuse.

15. The method as claimed in claim 12, wherein an optoelectronic device is created.

16. The optoelectronic device as claimed in claim 3, wherein the first electrode is designed in a layer-like manner and the first electrode and the second electrode are designed and arranged relative to the functional layer structure in such a way that the functional layer structure can be energized by means of the first and the second electrode in such a way that a current density at a position of the functional layer structure located within one of the electrode elements, as seen in projection onto a layer surface of the first electrode, differs from a current density at a position of the functional layer structure located centrally in the intermediate space between two boundary surfaces of the electrode elements, as seen in projection onto the surface layer of the first electrode, by less than 20% or by less than 5%.

17. The optoelectronic device as claimed in claim 1, wherein both in a region inside one of the electrode elements and in a region of the conductive structure between the electrode elements, the first electrode has a transparency to light of at least 75%, at a wavelength of 500 nm.

18. The optoelectronic device as claimed in claim 1, wherein the conductive structure comprises nano-conductive elements with a diameter of less than 50 nm, which act as the fuse.

19. The optoelectronic device as claimed in claim 1, wherein the electrode elements comprise a conductive layer, which comprises indium tin oxide.

20. The optoelectronic device as claimed in claim 1, wherein the electrode elements have an extension of less than 100 μm or less than 50 μm in each direction.
